(19) United States
(12) Patent Application Publication
(10) Pub. No.: US 2009/0085140 A1
(43) Pub. Date: Apr. 2, 2009

(54) FINGER TYPE PHOTODIODE AND METHOD OF MANUFACTURING THE SAME

(75) Inventors: Deuk Hee PARK, Seoul (KR); Kyoung Soo KWON, Yongin (KR); Chae Dong GO, Suwon (KR); Ha Woong JEONG, Suwon (KR)

Correspondence Address: LOWE HAUPTMAN HAM & BERNER, LLP, 1700 DIAGONAL ROAD, SUITE 300, ALEXANDRIA, VA, 22314, US

(73) Assignee: SAMSUNG ELECTRO-MECHANICS CO., LTD., Gyunggi-do (KR)

(21) Appl. No.: 11/967,968

(22) Filed: Dec. 31, 2007

(30) Foreign Application Priority Data
Sep. 27, 2007 (KR) 10-2007-0097371

(51) Int. Cl. H01L 31/0216; H01L 31/18

(52) U.S. Cl. 257/437; 438/72; 257/E31.121

(57) ABSTRACT

Provided are a finger type photodiode and a method of manufacturing the same, which can reduce noise by forming a shallow doping layer. The finger type photodiode includes a bottom substrate supporting layers to be formed thereon, an epitaxial layer formed on the bottom substrate, a finger doping layer formed in a finger shape on a top surface of the epitaxial layer, and a shallow doping layer formed with a shallow depth on an externally exposed top surface of the epitaxial layer and a top surface of the finger doping layer. Since the dangling bond generated on the epitaxial layer and the finger doping layer is reduced, noise can be reduced, thereby improving the light efficiency and reliability of the photodiode.

### CROSS-REFERENCE TO RELATED APPLICATIONS

This application claims the benefit of Korean Patent Application No. 10-2007-0097371 filed with the Korea Intellectual Property Office on Sep. 27, 2007, the disclosure of which is incorporated herein by reference.

### BACKGROUND OF THE INVENTION

1. Field of the Invention

The present invention relates to a finger type photodiode, which can reduce noise, and a method of manufacturing the same.

2. Description of the Related Art

Generally, an optical pickup is an important component used in an optical recording and reproducing apparatus that can read data from an optical recording medium or record data on the optical recording medium. The optical pickup includes a laser light source, a variety of lenses, reflective and transmissive components, and an optical detector.

When CD and DVD are used as the optical recording medium, a laser with an intrinsic wavelength must be used in the recording media so as to record data on or reproduce data from the different recording media. For example, in the case of the CD, a laser with a wavelength of 780 nm is used for data recording and reproduction. In the case of the DVD, a laser with a wavelength of 650 nm is used for data recording and reproduction.

Recently, many attempts have been made to develop composite optical pickup devices that can record data on and reproduce data from a variety of optical recording media. Especially, many researches have been conducted on Blue-ray disks with ultra-high data recording and reproduction capability and their drivers.

Hereinafter, a cell structure of a conventional photo diode integrated circuit (PDIC) and a conventional opto-electronic integrated circuit (OEID) and a photodiode of each cell, which can read data from a Blue-ray disk, will be described below with reference to the accompanying drawings.

FIG. 1 is a block diagram illustrating a cell structure of a conventional PDIC, and FIG. 2 is a cross-sectional view illustrating a conventional photodiode.

Referring to FIG. 1, a PDIC or OEID used in a Blue-ray disk player or read/write device using an ultraviolet (UV)-based laser with a wavelength of 405 nm is divided into four regions 1, 2, 3 and 4 and detects light applied thereto.

Each of the four regions 1, 2, 3 and 4 detects light applied thereto and converts the detected light into electric signals. In this way, data stored in the Blue-ray disk can be read.

Each cell of the PDIC is comprised of a photodiode. As illustrated in FIG. 2, the photodiode includes a bottom substrate 10 where P− type impurities are doped. An N− type epitaxial layer 20 is formed on the bottom substrate 10. An N− type diffusion layer 30 is formed at an upper portion of the epitaxial layer 20 by doping N− type impurities into the epitaxial layer 20.

In the conventional photodiode having the above-described structure, light incident from the outside reaches the epitaxial layer 20, which is a depletion region, and is converted into electric signal by electrons existing within the epitaxial layer 20.

However, in the Blue-ray method in which a wavelength of the incident light is less than 780 nm or 650 nm, a penetration depth of the incident light is gradually reduced. Thus, the incident light cannot reach the epitaxial layer 20 because it is blocked in the N− type diffusion layer 30. Thus, the light efficiency of the photodiode is reduced.

To solve the problem, the N− type diffusion layer 30 is modified into a finger type structure. FIGS. 3 and 4 are a cross-sectional view and a plan view, respectively, illustrating a finger type photodiode. Referring to FIGS. 3 and 4, an N− type diffusion layer 130 is formed in a finger shape on an epitaxial layer 120, so that the light incident from the outside reaches the top surface of the epitaxial layer 120, where the N− type diffusion layer 130 is not formed. Therefore, the incident light with a wavelength of 405 nm can be effectively converted into electric signal.

However, the conventional finger type photodiode has the following problems.

In the conventional finger type photodiode, dangling bond is generated in the externally exposed regions A and B of the epitaxial layer 20 and the N− type diffusion layer 30 by the process of planarizing the epitaxial layer 20. That is, incomplete covalent bond is formed in the regions A and B.

When light with a short wavelength of 405 nm is incident, the incident light reaches the top surface of the epitaxial layer 20 of the photodiode and is converted into electric signal. The incident light is not all converted into electric signal, but noise is generated because the incident light is obstructed by the dangling bond generated in the upper region B of the epitaxial layer 20.

Further, the dangling bond is also generated in the upper surface region A of the N− type diffusion layer 30, as well as the upper region of the epitaxial layer 20. Due to the dangling bond, noise is generated.

Accordingly, when a Blue-ray light with a short wavelength of 405 nm is incident, the incident light is not all converted into electric signal by the dangling bond in the upper regions A and B of the epitaxial layer 20 and the N− type diffusion layer 30 and thus noise is generated. Consequently, the light efficiency of the photodiode is lowered.

### SUMMARY OF THE INVENTION

An advantage of the present invention is that it provides a finger type photodiode and a method of manufacturing the same, in which dangling bond generated on an epitaxial layer can be reduced by forming a shallow doping layer with a shallow depth on a finger doping layer and an epitaxial layer, which is a depletion region, thereby reducing noise.

Additional aspects and advantages of the present general inventive concept will be set forth in part in the description which follows and, in part, will be obvious from the description, or may be learned by practice of the general inventive concept.

According to an aspect of the invention, a finger type photodiode includes: a bottom substrate supporting layers to be formed thereon; an epitaxial layer formed on the bottom substrate; a finger doping layer formed in a finger shape on a top surface of the epitaxial layer; and a shallow doping layer formed with a shallow depth on an externally exposed top surface of the epitaxial layer and a top surface of the finger doping layer.

An impurity type of the finger doping layer may be opposite to that of the shallow doping layer. The finger type photodiode may further include a poly buffered LOCOS (PBL) layer formed between the bottom substrate and the epitaxial layer. The finger type photodiode may further include an antireflective coating layer formed on the shallow doping layer.

The shallow doping layer may be formed with a thickness ranging from 0.03 μm to 0.10 μm, so that external incident light can reach the epitaxial layer, which is a depletion region, thereby improving the light efficiency of the photodiode.

According to another embodiment of the present invention, a method of manufacturing a finger type photodiode includes: preparing a bottom substrate; forming an epitaxial layer on the bottom substrate; doping impurities into the epitaxial layer to form a finger doping layer in a finger shape; and doping impurities on the entire surface of the finger doping layer to form a shallow doping layer with a shallow depth.

An impurity type of the finger doping layer may be opposite to that of the shallow doping layer. The method may further include forming a poly buffered LOCOS (PBL) layer on the bottom substrate. The method may further include forming an antireflective coating layer on the shallow doping layer.

The shallow doping layer may be formed to a thickness ranging from 0.03 μm to 0.10 μm.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram illustrating a cell structure of a conventional PDIC;

FIG. 2 is a cross-sectional view illustrating a conventional photodiode;

FIG. 3 is a cross-sectional view illustrating a finger type photodiode;

FIG. 4 is a plan view illustrating the finger type photodiode of FIG. 3;

FIGS. 5 and 6 are a sectional view and a plan view, respectively, illustrating a finger type photodiode according to an embodiment of the present invention;

FIGS. 7A to 7E are cross-sectional views illustrating a method of manufacturing a finger type photodiode according to an embodiment of the present invention; and

FIGS. 8 and 9 are cross-sectional views illustrating finger type photodiodes according to embodiments of the present invention.

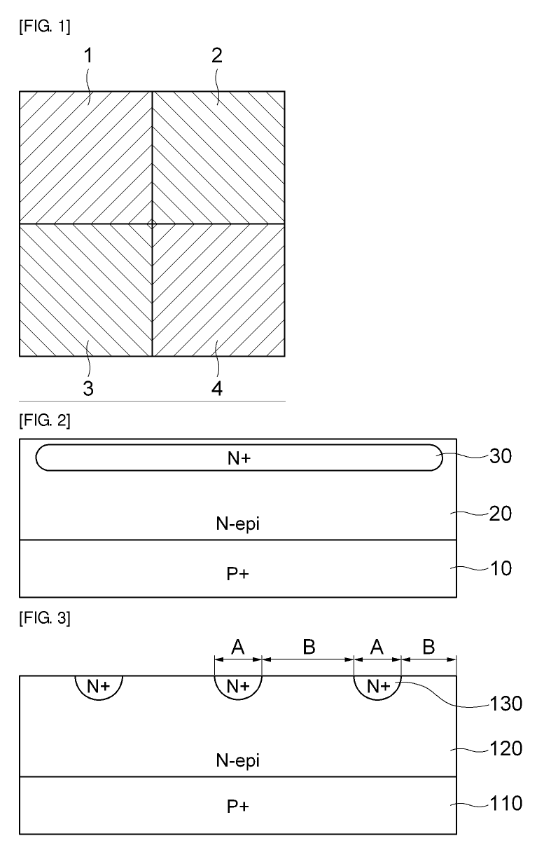

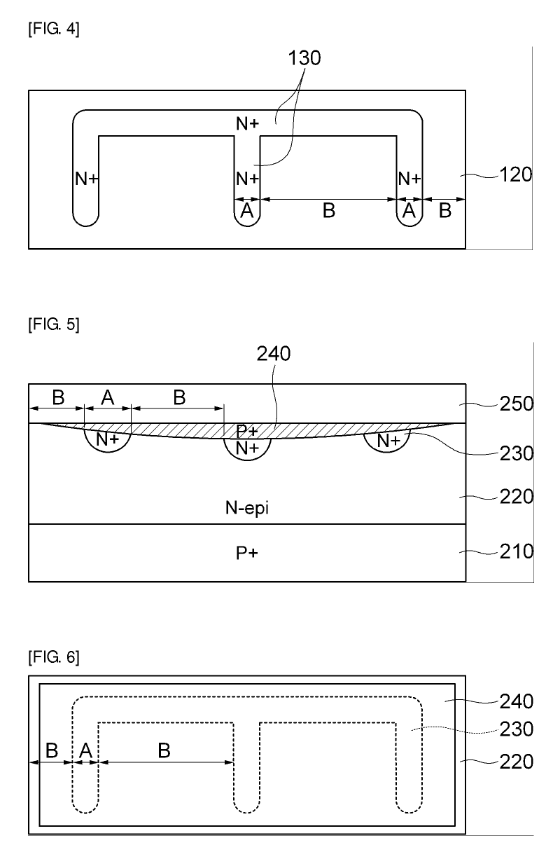

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures. In the drawings, the thicknesses of layers and regions are exaggerated for clarity.

Hereinafter, a finger type photodiode and a method of manufacturing the same according to embodiments of the present invention will be described in detail with reference to the accompanying drawings.

Finger Type Photodiode

A finger type photodiode according to an embodiment of the present invention will be described below in detail with reference to FIGS. 5 and 6.

FIGS. 5 and 6 are a sectional view and a plan view, respectively, illustrating a finger type photodiode according to an embodiment of the present invention.

Referring to FIG. 5, the finger type photodiode according to the embodiment of the present invention includes a bottom substrate 210, an epitaxial layer 220, a finger doping layer 230, and a shallow doping layer 240. The bottom substrate 210 supports layers formed thereon. The epitaxial layer 220 is formed on the bottom substrate 210. The finger doping layer 230 is formed in a finger shape with a predetermined depth from the top surface of the epitaxial layer 220. The shallow doping layer 240 is doped to a shallow depth on the externally exposed top surface of the epitaxial layer 220 and the top surface of the finger doping layer 230.

The bottom substrate 210 is formed by doping high-concentration P+ type impurities into a semiconductor substrate, for example, a silicon substrate. The epitaxial layer 220 formed on the bottom substrate 210 is formed by N− epi growth. An N+ type impurity such as arsenic (As) is doped on the epitaxial layer 220.

Specifically, as illustrated in FIG. 6, the finger doping layer 230 is formed with finger type patterns on the top surface of the epitaxial layer 220, not on the entire top surface of the epitaxial layer 220. Therefore, light incident from the outside is not absorbed into the finger doping layer 230, thereby improving the light efficiency of the photodiode.

In addition, the shallow doping layer 240 is formed on the epitaxial layer 220, where the finger doping layer 230 is formed, in order to prevent the occurrence of noise, which has been generated by dangling bond in a depletion region B of the epitaxial layer 220 and a top surface region A of the finger doping layer 230.

At this point, the shallow doping layer 240 is formed by doping impurities having a conductivity opposite to that of the finger doping layer 230 into the epitaxial layer 220 where the finger doping layer 230 is formed. That is, since the impurities doped into the finger doping layer 230 are N+ type impurities, the shallow doping layer 240 is formed by doping P+ type impurities such as boron (B).

Preferably, the shallow doping layer 240 is formed with a thickness ranging from 0.03 μm to 0.1 μm such that external incident light with a short wavelength of 405 nm can reach the epitaxial layer 220. The incident light with the short wavelength of 405 nm has a penetration depth of about 0.14 μm with respect to the epitaxial layer 220. Thus, if the shallow doping layer 240 is formed with a thickness of less than 0.03 μm, it is difficult to remove dangling bond generated in a region B above the epitaxial layer 220 and a region A above the finger doping layer 230. If the shallow doping layer 240 is formed with a thickness of more than 0.1 μm, the incident light cannot pass through the shallow doping layer 240 and reach the epitaxial layer 220 and the finger doping layer 230, thus lowering the light efficiency of the photodiode. Accordingly, it is preferable that the shallow doping layer 240 is formed with a thickness ranging from 0.03 μm to 0.1 μm.

In the finger type photodiode according to the embodiment of the present invention, the shallow doping layer 240, which is formed on the epitaxial layer 220 and the finger doping layer 230, is bonded to the dangling bond generated by the planarization process of the epitaxial layer 220 and the finger doping layer 230. Consequently, the dangling bond is removed. Further, the noise generated in the regions A and B defined above the epitaxial layer 220 and the finger doping layer 230 can be reduced, which makes it possible to enhance the light efficiency with respect to the incident light.

A poly buffered LOCOS (PBL) layer, which is a field oxide layer, may be further formed between the bottom substrate 210 and the epitaxial layer 220.

In addition, an antireflective coating layer 250 may be further formed on the shallow doping layer 240. The antireflective coating layer 250 can prevent the external incident light from being reflected by the photodiode.

Method Of Manufacturing Finger Type Photodiode

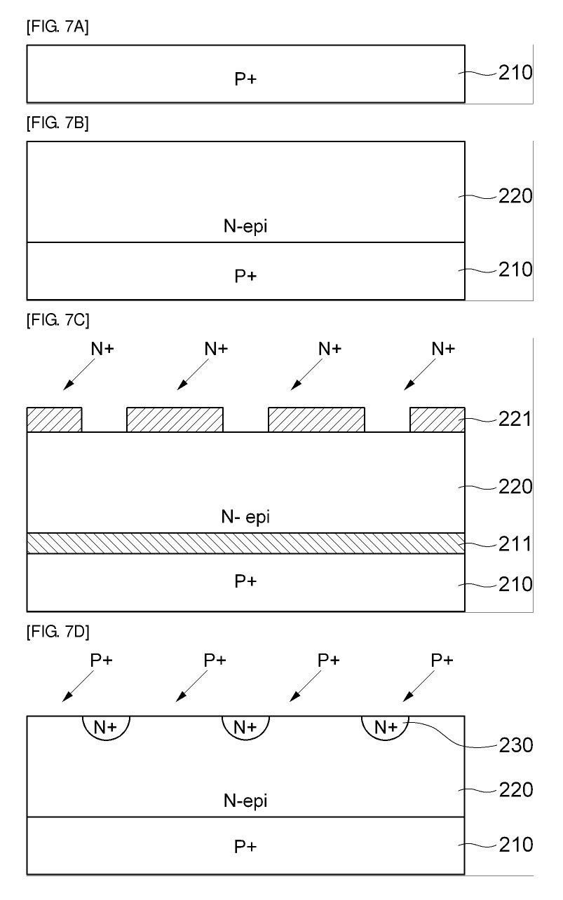

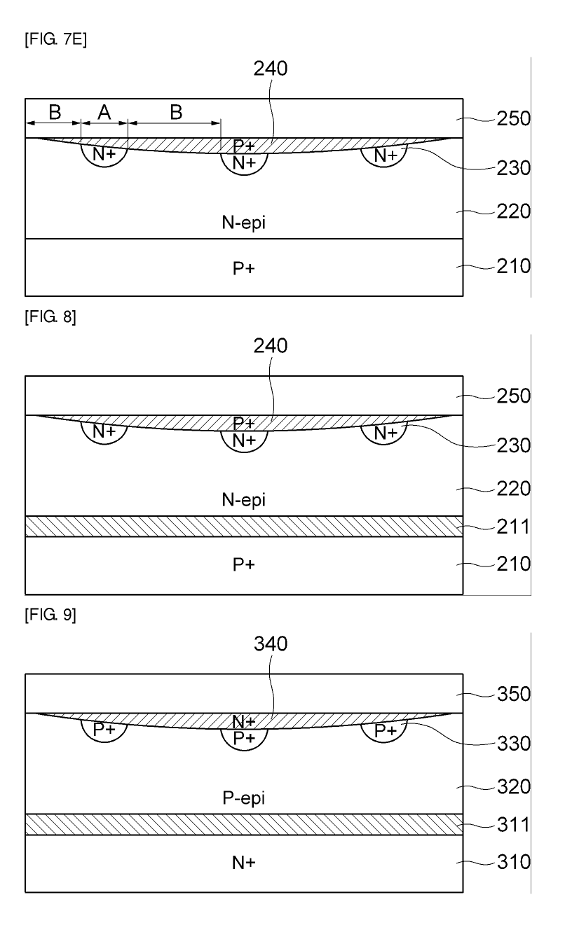

A method of manufacturing a finger type photodiode according to an embodiment of the present invention will be described in detail with reference to FIGS. 7 to 9.

FIGS. 7A to 7E are cross-sectional views illustrating a method of manufacturing a finger type photodiode according to an embodiment of the present invention.

Referring to FIG. 7A, a bottom substrate 210 is prepared for supporting layers that will be formed thereon by subsequent processes. P+ type impurities such as boron (B) are doped into the bottom substrate 210.

Referring to FIG. 7B, after doping the P+ type impurities into the bottom substrate 210, an epitaxial layer 220 is formed on the bottom substrate 210, and an upper surface of the epitaxial layer 220 is planarized. Preferably, the epitaxial layer 220 is formed by a chemical vapor deposition (CVD) process.

Referring to FIG. 7C, after forming the epitaxial layer 220, a photoresist layer 221 is coated with a predetermined thickness on the epitaxial layer 220. An exposure and development process is performed on the coated photoresist layer, so that the photoresist layer formed in a region where a finger doping layer will be formed is removed. Then, N+ type impurities such as arsenic (As) are doped using the photoresist layer 221 as a mask. Meanwhile, before forming the epitaxial layer 220, a PBL layer 211 may be formed on the bottom substrate 210.

Referring to FIG. 7D, impurities are doped into the epitaxial layer 220 to form a finger doping layer 230 in a finger shape with a predetermined depth from the top surface of the epitaxial layer 220. Then, the photoresist layer 221 is removed.

A shallow doping layer 240 with a shallow depth is formed by doping P+ type impurities into the epitaxial layer 220, where the finger doping layer 230 is formed. The formation of the shallow doping layer 240 aims to remove the dangling bond generated by the planarization process in an upper region of the externally exposed epitaxial layer 220 and an upper region of the finger doping layer 230. Since the shallow doping layer 240 removes the dangling bond generated in the upper region of the epitaxial layer 220 and the upper region of the finger doping layer 230, noise that has been generated by the dangling bond can be reduced, which makes it possible to enhance the light efficiency of the photodiode.

Specifically, it is preferable that the shallow doping layer 240 is formed with a thickness ranging from 0.03 μm to 0.1 μm such that external incident light with a short wavelength of 405 nm can reach the epitaxial layer 220. The incident light with the short wavelength of 405 nm has a penetration depth of about 0.14 μm with respect to the epitaxial layer 220. Thus, if the shallow doping layer 240 is formed with a thickness of less than 0.03 μm, it is difficult to remove dangling bond generated in the upper region of the epitaxial layer 220 and the upper region of the finger doping layer 230. If the shallow doping layer 240 is formed with a thickness of more than 0.1 μm, the incident light cannot pass through the shallow doping layer 240 and reach the epitaxial layer 220 and the finger doping layer 230, thus lowering the light efficiency of the photodiode. Accordingly, it is preferable that the shallow doping layer 240 is formed to a thickness ranging from 0.03 μm to 0.1 μm.

Referring to FIG. 7E, an antireflective coating layer 250 may be further formed on the shallow doping layer 240 so as to prevent the incident light from being reflected by the photodiode.

Referring to FIG. 8, a PBL layer 211, which is a field oxide layer, may be further formed on the bottom substrate 210. FIG. 9 is a cross-sectional view of a finger type photodiode according to another embodiment of the present invention. As illustrated in FIG. 9, the finger type photodiode can be manufactured with opposite type to that of FIG. 5.

According to the present invention, the shallow doping layer with a shallow depth is formed with an impurity type opposite to that of the finger doping layer on the filter doping layer and the epitaxial layer. Thus, the dangling bond generated on the epitaxial layer and the finger doping layer can be reduced and noise can be reduced, thereby improving the light efficiency and reliability of the photodiode.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A finger type photodiode comprising:
a bottom substrate supporting layers to be formed thereon;
an epitaxial layer formed on the bottom substrate;
a finger doping layer formed in a finger shape on a top surface of the epitaxial layer; and
a shallow doping layer formed with a shallow depth on an externally exposed top surface of the epitaxial layer and a top surface of the finger doping layer.

2. The finger type photodiode according to claim 1, wherein an impurity type of the finger doping layer is opposite to that of the shallow doping layer.

3. The finger type photodiode according to claim 1, further comprising:
a poly buffered LOCOS (PBL) layer formed between the bottom substrate and the epitaxial layer.

4. The finger type photodiode according to claim 1, further comprising:
an antireflective coating layer formed on the shallow doping layer.

5. The finger type photodiode according to claim 1, wherein the shallow doping layer is formed with a thickness ranging from 0.03 μm to 0.10 μm.

6. A method of manufacturing a finger type photodiode, comprising:
preparing a bottom substrate;
forming an epitaxial layer on the bottom substrate;
doping impurities into the epitaxial layer to form a finger doping layer in a finger shape; and
doping impurities on the entire surface of the finger doping layer to form a shallow doping layer with a shallow depth.

7. The method according to claim 6, wherein an impurity type of the finger doping layer is opposite to that of the shallow doping layer.

8. The method according to claim 6, further comprising:
forming a poly buffered LOCOS (PBL) layer on the bottom substrate.

9. The method according to claim 6, further comprising:
forming an antireflective coating layer on the shallow doping layer.

10. The method according to claim 6, wherein the shallow doping layer is formed to a thickness ranging from 0.03 μm to 0.10 μm.
